(19) United States
(12) Patent Application Publication
(10) Pub. No.: US 2025/0007282 A1
(43) Pub. Date: Jan. 2, 2025

(54) DIGITAL TWIN-BASED APPARATUS FOR PROVIDING OPERATION AND MAINTENANCE MANAGEMENT PLATFORM SERVICE FOR PHOTOVOLTAIC POWER GENERATION SYSTEM, AND METHOD FOR OPERATING AND MAINTAINING PHOTOVOLTAIC POWER GENERATION SYSTEM BY USING SAME

(71) Applicants: Ki Ju PARK, Seoul (KR); Jae Seong PARK, Seoul (KR); Sae Hee PARK, Seoul (KR)

(72) Inventors: Ki Ju PARK, Seoul (KR); Jae Seong PARK, Seoul (KR); Sae Hee PARK, Seoul (KR)

(21) Appl. No.: 18/700,713

(22) PCT Filed: Sep. 26, 2022
(86) PCT No.: PCT/KR2022/014371

§ 371 Date: Apr. 12, 2024

(30) Foreign Application Priority Data
Oct. 14, 2021 (KR) 10-2021-0136847

(51) Int. Cl. H02J 3/00; G06F 30/20

(52) U.S. Cl. CPC H02J 3/004; G06F 30/20; H02J 2203/20

(57) ABSTRACT

The present invention relates to an apparatus for providing an operation and maintenance management platform service for a photovoltaic power generation system, and a method for operating and maintaining a photovoltaic power generation system by using same, the apparatus implementing a virtually-simulated photovoltaic power generation system corresponding to each of one or more actual photovoltaic power generation systems, and then predicting whether there is a failure in any actual photovoltaic power generation system on the basis of the difference between actually measured data on the actual photovoltaic power generation system and estimated data on the corresponding simulated photovoltaic power generation system, notifying a system manager, adjacent to an actual photovoltaic power generation system in which a failure is predicted, of same from among pre-registered system managers.

### TECHNICAL FIELD

The present invention relates to a photovoltaic power generation system, and more particularly to a digital twin-based apparatus for providing an operation and maintenance (hereinafter referred to as “O&M”) management platform service of a photovoltaic power generation system and a method of performing operation and maintenance of a photovoltaic power generation system using the same.

### BACKGROUND ART

A photovoltaic power generation system is a power generation system that converts energy received from the sun into electricity, and the merit thereof is increasing as environmental requirements for non-pollution and reduction in use of fossil fuels increase.

In addition, the importance of operation and maintenance (O&M) is increasingly emphasized for the long-term development of photovoltaic power generation systems and stable revenue generation. A photovoltaic power plant is a long-term investment having an installation period of 20 to 25 years, but due to the high initial investment, there is no guarantee that the plant will continue to generate high profits.

Photovoltaic operation and maintenance (O&M) is an essential element of power plant operation to maintain a stable power supply, and may be defined in a narrow sense as simple equipment maintenance and repair, and in a broad sense as extending lifespan and improving performance.

Therefore, photovoltaic operation and maintenance (O&M) aims to minimize power generation losses by identifying factors that impede the optimal power generation of the photovoltaic power generation system in advance or responding quickly to failures when the failures occur.

However, the factors that impede the power generation are very diverse. For example, there are discoloration, cracking, and hot spots of solar cells, natural degradation of solar cells, short lifespan of inverters, snow, wind, dirt, and other natural environments. In addition, an increase in system failure and system aging due to an increase in the cumulative number of photovoltaic facilities are also among the factors that impede power generation.

As these numerous factors appear unexpectedly in various facilities, continuous maintenance is essential for the operation of the photovoltaic power generation system, but it is very difficult to check all these various factors with the naked eye.

In order to solve this problem, Korean Registered Patent No. 10-1728692 discloses a failure prediction and monitoring system and method of a photovoltaic module. According to the patent, by constituting a system for determining whether the amount of photovoltaic power generation that changes over time changes in accordance with the appropriate theoretical amount of power generation according to seasonal or real-time weather changes, it is possible to accurately determine whether a photovoltaic power generation module has failed. In addition, according to the patent, if failure or abnormality is predicted, the same is transmitted to a user terminal in real time.

However, the above prior art document only predicts the failure of the photovoltaic power generation system and transmits information thereabout to the user, but does not analyze or manage whether a user who receives the information has actually responded appropriately to the failure of the system and how it has beneficially affected the power generation, and does not perform active processing to recover from the failure, thereby limiting effective operation and maintenance of the photovoltaic power generation system.

In addition, the prior art document only transmits the operating state of the photovoltaic power generation system to a user (e.g., a system operator or administrator) based on preset criteria or only when an error occurs, and therefore the user is not free to check the operating state of the photovoltaic power generation system at any desired time.

Furthermore, the prior art document provides the operating state of the photovoltaic power generation system in the form of an alarm or a numerical value, which makes it difficult for a user (e.g., a system operator) having no specialized knowledge of the system to intuitively quickly recognize the operating state of the photovoltaic power generation system.

### PRIOR ART DOCUMENTS

### Patent Documents

(Patent Document 1) Korean Registered Patent No. 10-1728692

### DISCLOSURE

### Technical Problem

Therefore, it is an object of the present invention to provide an apparatus for providing an operation and maintenance management platform service of a photovoltaic power generation system configured to, after implementing a virtual simulated photovoltaic power generation system corresponding to each of at least one actual photovoltaic power generation system, predict whether failure of an arbitrary actual photovoltaic power generation system has failed based on the difference between actual measured data of the actual photovoltaic power generation system and the theoretically estimated data of the simulated photovoltaic power generation system corresponding thereto and to notify a system administrator adjacent to the actual photovoltaic power generation system that is predicted to fail, among pre-registered system administrators, of the same such that the system administrator can quickly respond to the failure and a method of performing operation and maintenance of a photovoltaic power generation system using the same.

It is another object of the present invention to provide an apparatus for providing an operation and maintenance management platform service of a photovoltaic power generation system configured to provide differentiated compensation to a system administrator who participated in recovering from failure of the photovoltaic power generation system according to the response speed such that system administrator can more actively respond to the failure of the photovoltaic power generation system and a method of performing operation and maintenance of a photovoltaic power generation system using the same.

It is another object of the present invention to provide an apparatus for providing an operation and maintenance management platform service of a photovoltaic power generation system configured to provide operation information of an arbitrary photovoltaic power generation system in response to a request of a user who is allowed to access the operation information of the photovoltaic power generation system such that the user can freely check the operating state of the photovoltaic power generation system at any desired time and a method of performing operation and maintenance of a photovoltaic power generation system using the same.

It is a further object of the present invention to provide an apparatus for providing an operation and maintenance management platform service of a photovoltaic power generation system configured to provide real-time operation information of a virtual simulated photovoltaic power generation system as a three-dimensional image using digital twin technology such that a user having no specialized knowledge of the system can intuitively quickly recognize the operating state of the photovoltaic power generation system and a method of performing operation and maintenance of a photovoltaic power generation system using the same.

### Technical Solution

In order to accomplish the above objects, an apparatus for providing an operation and maintenance management platform service of a photovoltaic power generation system according to the present invention includes a simulated photovoltaic power generation system generation unit configured to generate a simulated photovoltaic power generation system having the same system specifications and installation information as each actual photovoltaic power generation system for each of at least one actual photovoltaic power generation system, a system information storage unit configured to store system specifications and installation information of each of the actual photovoltaic power generation systems, point-specific actual measurement data collected in real time during operation, and simulated photovoltaic power generation system information corresponding thereto, a failure diagnosis unit configured to estimate point-specific output data when the simulated photovoltaic power generation system is virtually operated under the same conditions as operating conditions of the actual photovoltaic power generation system corresponding thereto and to compare the estimated data with the actual measurement data to predict whether the actual photovoltaic power generation system has failed, an administrator information storage unit configured to store system administrator information registered as system administrators capable of performing recovery operation in the event of failure of the actual photovoltaic power generation system, and a failure prediction information transmission unit configured to transmit failure prediction information to at least one of the system administrators registered in the administrator information storage unit when failure of an arbitrary first actual photovoltaic power generation system is predicted by the failure diagnosis unit.

On the other hand, in order to accomplish the above objects, a method of performing operation and maintenance of a photovoltaic power generation system according to the present invention is a method of performing operation and maintenance of a photovoltaic power generation system using an apparatus for providing an operation and maintenance management platform service of a photovoltaic power generation system, the apparatus configured to store arbitrary actual photovoltaic power generation system information and virtual simulated photovoltaic power generation system information implemented so as to have the same system specifications and installation information as each actual photovoltaic power generation system, the method including an administrator information storage step of, by the apparatus for providing the operation and maintenance management platform service, storing system administrator information registered as system administrators capable of performing recovery operation in the event of failure of the photovoltaic power generation system, a failure diagnosis step of, by the apparatus for providing the operation and maintenance management platform service, estimating point-specific output data when the simulated photovoltaic power generation system is virtually operated under the same conditions as operating conditions of the actual photovoltaic power generation system corresponding thereto and predicting whether the actual photovoltaic power generation system has failed based on actual measured data collected for each point during operation of the actual photovoltaic power generation system and the estimated data, an administrator detection step of, by the apparatus for providing the operation and maintenance management platform service, detecting at least one of the system administrators registered in the administrator information storage step when failure of an arbitrary first actual photovoltaic power generation system is predicted in the failure diagnosis step, and a failure prediction information transmission step of, by the apparatus for providing the operation and maintenance management platform service, transmitting failure prediction information of the first actual photovoltaic power generation system to the detected system administrator.

### Advantageous Effects

As is apparent from the above description, an apparatus for providing an operation and maintenance management platform of a photovoltaic power service generation system and a method of performing operation and maintenance of a photovoltaic power generation system using the same have the effect of, after implementing a virtual simulated photovoltaic power generation system corresponding to each of at least one actual photovoltaic power generation system, predicting whether an arbitrary actual photovoltaic power generation system has failed based on the difference between actual measured data of the actual photovoltaic power generation system and the theoretically estimated data of the simulated photovoltaic power generation system corresponding thereto and notifying a system administrator adjacent to the actual photovoltaic power generation system that is predicted to fail, among pre-registered system administrators, of the same such that the system administrator can quickly respond to the failure.

In addition, the present invention has the effect of providing differentiated compensation to a system administrator who participated in recovering from failure of the photovoltaic power generation system according to the response speed such that the system administrator can more actively respond to the failure of the photovoltaic power generation system.

In addition, the present invention has the effect of providing operation information of an arbitrary photovoltaic power generation system in response to a request of a user who is allowed to access the operation information of the photovoltaic power generation system such that the user can freely check the operating state of the photovoltaic power generation system at any desired time.

In addition, the present invention has the effect of providing real-time operation information of a virtual simulated photovoltaic power generation system as a three-dimensional image using digital twin technology such that a user having no specialized knowledge of the system can intuitively quickly recognize the operating state of the photovoltaic power generation system.

### DESCRIPTION OF DRAWINGS

FIG. 1 is a schematic view showing a system configuration for providing an O&M management platform service of a photovoltaic power generation system according to one embodiment of the present invention.

FIG. 2 is a schematic block diagram showing an O&M management platform server of a photovoltaic power generation system according to one embodiment of the present invention.

FIG. 3 is a view showing an example of a field structure of a database for managing system administrator information according to one embodiment of the present invention.

FIG. 4 is a schematic block diagram showing a failure diagnosis unit according to one embodiment of the present invention.

FIG. 5 is a schematic flowchart showing a method of performing operation and maintenance of a photovoltaic power generation system using an O&M management platform server of a photovoltaic power generation system according to one embodiment of the present invention.

### BEST MODE

Hereinafter, embodiments of the present invention will be described with reference to the accompanying drawings, and the present invention will be described in detail to the extent to which a person having ordinary skill in the art to which the present invention pertains can easily implement the present invention. However, the present invention may be implemented in various different forms and is not limited to the embodiments described herein. Meanwhile, parts having no relation to the description of the present invention are omitted from the drawings in order to clearly describe the present invention, and similar parts are denoted by similar reference numerals throughout the specification. In addition, parts that can be easily understood by those skilled in the art even though a detailed description thereof is omitted will not be described.

When a certain part includes a certain component in the specification and the claims, this means that another component is not excluded but is further included, unless mentioned otherwise.

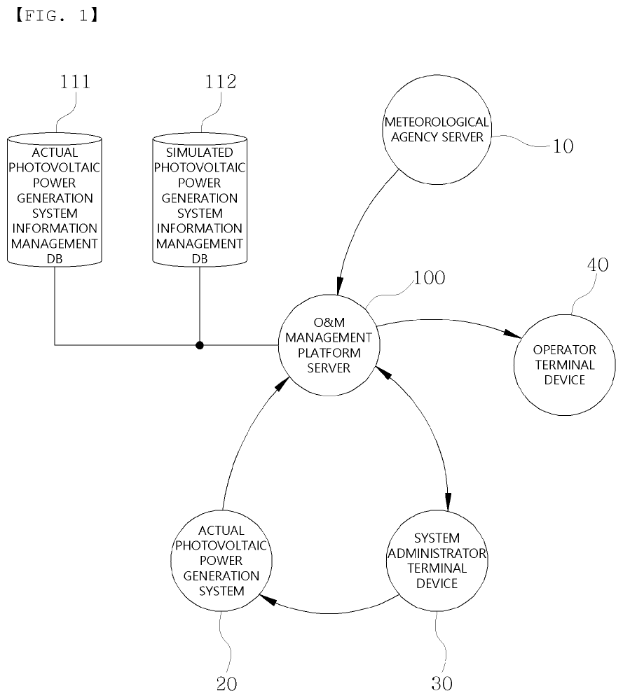

FIG. 1 is a schematic view showing a system configuration for providing an O&M management platform service of a photovoltaic power generation system according to one embodiment of the present invention. Referring to FIG. 1, an O&M management platform server 100 for providing an O&M management platform service of a photovoltaic power generation system according to one embodiment of the present invention includes an actual photovoltaic power generation system information management DB 111 and a simulated photovoltaic power generation system information management DB 112, and is connected to a meteorological agency server 10, an actual photovoltaic power generation system 20, a system administrator terminal device 30, and an operator terminal device 40.

In this context, the actual photovoltaic power generation system 20 refers to a real photovoltaic power generation system existing in the real world, and the simulated photovoltaic power generation system refers to a virtual system having the same system specifications and installation information as the actual photovoltaic power generation system 20 and implemented so as to have the same operating conditions as the actual photovoltaic power generation system 20. That is, the simulated photovoltaic power generation system refers to a system for estimating the power generation when the actual photovoltaic power generation system 20 is operated in an optimal state.

Here, the “system specifications,” which refers to the performance of the actual photovoltaic power generation system 20 and hardware elements configured to determine the same, may include the overall output capacity of the actual photovoltaic power generation system 20, the unit capacity of each photovoltaic module, the number of photovoltaic modules, the number of string circuits, the number of junction boxes, the capacity of each inverter, and the number of installed inverters, and the “installation information” may include the installation location of the actual photovoltaic power generation system 20 (e.g., geographic information, including latitude and longitude, and local information).

In addition, the “operating conditions” may include environmental information of the area where the actual photovoltaic power generation system 20 is installed (e.g., climate conditions), daily operating hours, and degree of aging, and the “optimal state,” which refers to the most ideal state in which the actual photovoltaic power generation system 20 is not subject to any failure or any influence that hinders normal operation thereof, may include the case in which the solar strings, the junction boxes, and the inverters included in the actual photovoltaic power generation system 20 are in the best possible state for the type/rated capacity of a power plant, the electrical characteristics including the connection circuits and wiring states are free from errors, and the degree of aging is within the minimum acceptable range.

As described above, the simulated photovoltaic power generation system is a virtual photovoltaic power generation system that has the same configurations as the system specifications of the actual photovoltaic power generation system and that is implemented to operate in the same installation location (e.g., geographic information including latitude/longitude) and environment (e.g., climate conditions), and may estimate point-specific output data of the actual photovoltaic power generation system. In this case, the point refers to any point from which information capable of determining the performance of the actual photovoltaic power system, generation such as string input/output, junction box input/output terminals, and inverter input/output terminals, is output.

In addition, the simulated photovoltaic power generation system may be implemented as a three-dimensional image using known digital twin technology, and to this end, three-dimensional design drawings of the actual photovoltaic power generation system, geographic information about the installation location (e.g., longitude and latitude), and 360-degree stereoscopic camera information may be used.

The O&M management platform server 100 estimates point-specific output data of the actual photovoltaic power generation system 20, and compares the estimated data with actual measurement data collected at the point to determine whether the actual photovoltaic power generation system 20 has failed.

To this end, the Q&M management platform server 100 stores in advance past power generation information based on past environmental data (e.g., climate conditions) of the area where the actual photovoltaic power generation system 20 is installed, receives, from the meteorological agency server 10, weather information including weather prediction information (e.g., temperature, the amount of precipitation, wind direction, wind speed, humidity, sunlight, and fine dust concentration on a particular day or during a particular period of time) of the area where the actual photovoltaic power generation system 20 is installed, and estimates the point-specific output data of the actual photovoltaic power generation system 20 based on the past environmental data and the received weather information. At this time, the O&M management platform server 100 may estimate the point-specific output data for each date corresponding to the weather information.

In addition, the Q&M management platform server 100 may collect the point-specific actual measurement data from the actual photovoltaic power generation system 20, and may compare the same with the estimated data to predict whether the actual photovoltaic power generation system has failed. In this case, the actual measurement data is data output from each of the points (e.g., string input/output, junction box input/output terminals, and inverter input/output terminals) of the actual photovoltaic power generation system 20, and may include the output current/output voltage/output power/temperature/humidity of each thereof. For example, the Q&M management platform server 100 may collect output current/output voltage/output power/temperature/humidity measurement values for each string constituting the actual photovoltaic power generation system 20, and may compare the same with the estimated data of each of the strings to predict whether each of the strings constituting the actual photovoltaic power generation system 20 has failed. That is, the Q&M management platform server 100 may compare the string-unit actual measurement data with the estimated data of each of the strings, and when the difference value deviates from an error range, the Q&M management platform server may predict that failure has occurred in the string.

In addition, the Q&M management platform server 100 may determine whether the failure is caused by leakage current, contamination of the photovoltaic module, or partial breakage of the photovoltaic module based on the range of the difference value. This is because the output degradation of the actual measurement data caused by the leakage current is much greater than the output degradation caused by the contamination or partial breakage of the photovoltaic module.

Meanwhile, when failure of the actual photovoltaic power generation system 20 is predicted as a result of the comparison between the actual power generation and the estimated power generation, the Q&M management platform server 10 transmits the failure information to the system administrator terminal device 30 located within a predetermined distance from the actual photovoltaic power generation system 20 such that system administrator terminal device can quickly respond to the failure.

To this end, the Q&M management platform server 10 may store geographic information (e.g., latitude/longitude) of the location where the actual photovoltaic power generation system 20 is installed and real-time location information of the system administrator terminal device 30, and may transmit the failure information to the system administrator terminal device 30 capable of arriving at the actual photovoltaic power generation system 20, failure of which within a few minutes is predicted.

In addition, the Q&M management platform server 10 may provide real-time operation information of the actual photovoltaic power generation system 20 in the form of a virtual three-dimensional image in response to a request from the operator (or user) terminal device 40 that operates the actual photovoltaic power generation system 20.

To this end, the Q&M management platform server 10 may reflect the real-time operation information to manage the simulated photovoltaic power generation system 20 implemented as a three-dimensional image. For example, the Q&M management platform server 10 may implement the simulated photovoltaic power generation system based on the system specifications (e.g., maximum output power, the number of solar cell strings, the number of junction boxes, and the number of inverters) of the actual photovoltaic power generation system 20 in the form of a three-dimensional image, and may reflect the real-time operation information by overwriting the actual measurement data or the estimated data on the three-dimensional image.

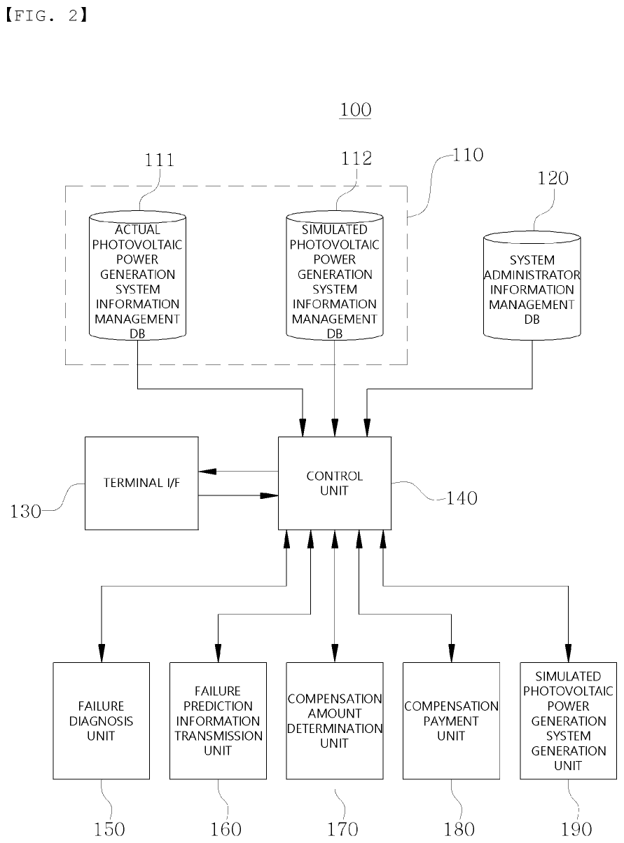

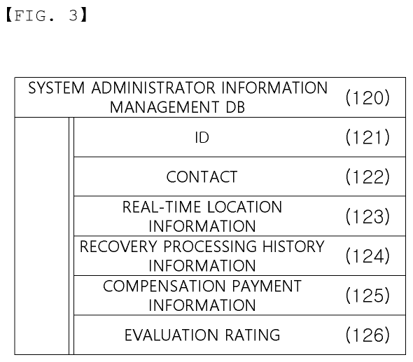

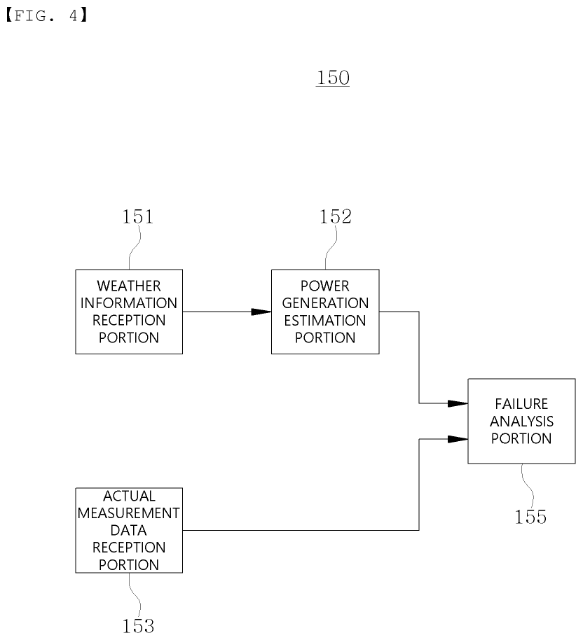

FIG. 2 is a schematic block diagram showing an O&M management platform server of a photovoltaic power generation system according to one embodiment of the present invention, FIG. 3 is a view showing an example of a field structure of a database for managing system administrator information according to one embodiment of the present invention, and FIG. 4 is a schematic block diagram showing a failure diagnosis unit according to one embodiment of the present invention.

Referring to FIGS. 1 to 4, the O&M management platform server 1 according to the embodiment of the present invention may include a system information management DB 110, a system administrator information management DB 120, a terminal interface unit (I/F) 130, a control unit 140, a failure diagnosis unit 150, a failure prediction information transmission unit 160, a compensation amount determination unit 170, a compensation payment unit 180, and a simulated photovoltaic power generation system generation unit 190.

The system information management DB 110 stores/manages information about the photovoltaic power generation system subject to O&M management. That is, the system information management DB 110 stores/manages system specifications and installation information of each of the actual photovoltaic power generation systems 20, point-specific actual measurement data collected in real time during operation, and simulated photovoltaic power generation system information. To this end, the system information management DB 110 may include an actual photovoltaic power generation system information management DB 111 configured to store/manage information of at least one actual photovoltaic power generation system actually installed in an arbitrary area and a simulated photovoltaic power generation system information management DB 112 configured to store/manage virtual simulated photovoltaic power generation system information corresponding to the at least one actual photovoltaic power generation system.

The actual photovoltaic power generation system information management DB 111 may include a unique number for each of the actual photovoltaic power generation systems, initial system specification information of the actual photovoltaic power generation system, periodically updated real-time system specification information (e.g., system specification information having system aging and system failure information reflected therein), geographic information of the area in which the actual photovoltaic power generation system is installed (e.g., latitude, longitude, and local information), a power generation estimate value established at the time of design, past power generation information based on past environmental data (e.g., climate conditions) during a predetermined period of time (e.g., 10 years), point-specific actual measurement data collected in real time, and installation date, and simulated photovoltaic power generation system identification information.

In this case, the optimal power generation estimate value is an optimal power generation estimate value (i.e., a point-specific optimal estimate output value) predicted at the installation location, and may be calculated by applying the average value of insolation over a 10-year period for the location, and the average power generation of a photovoltaic power generation system located within a predetermined radial distance (e.g., 500 meters) from the installation location using any of various known methods.

Meanwhile, the optimal power generation estimate value may be utilized in the future to predict whether the system will fail due to aging. For example, the control unit 140 may accumulatively manage the actual measurement data stored in the actual photovoltaic power generation system information management DB 111 to calculate the average power generation of the actual photovoltaic power generation system during a predetermined period of time, may monitor the difference between the average power generation and the optimal power generation estimate value, and may predict that failure of the actual photovoltaic power generation system has occurred when the difference exceeds a predetermined value or when the change in the difference rapidly increases. The simulated photovoltaic power generation system information management DB 112 may store simulated photovoltaic power generation system information corresponding to at least one actual photovoltaic power generation system, wherein the simulated photovoltaic power generation system information includes a unique number of each simulated photovoltaic power generation system, simulated system specification information reflecting real-time system specifications of the actual photovoltaic power generation system to which the simulated photovoltaic power generation system corresponds, estimated data estimated using the simulated system specification information, and identification information of the actual photovoltaic power generation system. In this case, the simulated system specification information refers to system specifications reflecting the real-time system specifications when the system specifications of the actual photovoltaic power generation system have changed due to aging and failure (i.e., age change).

For example, the simulated photovoltaic power generation system information management DB 112 may store simulated photovoltaic power generation system information implemented based on the system specifications (e.g., maximum output power, the number of solar cell strings, the number of junction boxes, and the number of inverters) of the actual photovoltaic power generation system 20.

In addition, the simulated photovoltaic power generation system information management DB 112 stores image information implementing the actual photovoltaic power generation system 20 as a three-dimensional image, and provides real-time operation information of the actual photovoltaic power generation system 20 in the form of a virtual three-dimensional image in response to a request from the operator (or user) terminal device 40 that operates the actual photovoltaic power generation system 20, wherein the real-time operation information is reflected by overwriting the actual measurement data or the estimated data on the three-dimensional image.

The system administrator information management DB 120 stores information of administrators registered as system administrators who can perform recovery operation in the event of failure of the photovoltaic power generation system. An example of a field structure of the system administrator information management DB 120 is illustrated in FIG. 3. Referring to FIG. 3, the system administrator information management DB 120 may store identification information (ID) 121 of the system administrator, terminal device information (e.g., contact or access information) 122 of the system administrator, real-time location information 123 of the system administrator, recovery processing history information 124, compensation payment information 125, and evaluation rating 126. In this case, the real-time location information 123 may be location information received from the terminal device of the system administrator in a preset time period (e.g., 1 minute or 30 seconds). The recovery processing history information 124, which is the recovery processing history information of the system administrator, may be information received via the terminal interface unit 130, a description of which will follow. In this case, the recovery processing history information may be information generated using a response message (i.e., a response message to the failure prediction information) and a processing result message (i.e., a failure recovery processing result message) transmitted by the system administrator, and may store the reception time of the response message and the processing result message together.

The compensation payment information 125 is compensation information paid to the system administrator, and may include information including a compensation amount determined by the compensation amount determination unit 170, a description of which will follow, the compensation payment date, and the number of times of compensation payment. At this time, the compensation amount determination unit 170 may calculate the duration from the reception time of the response message to the reception time of the processing result message or the duration from the prediction time of the failure to the reception time of the processing result message, and determine the compensation amount such that the duration and the compensation amount are inversely proportional.

The evaluation rating 126 may store the evaluation rating of the system administrator. At this time, the evaluation rating may be determined based on the processing result message, the compensation payment information, and the evaluation contents of the system operator.

Meanwhile, the compensation amount determination unit 170, a description of which will follow, may consider the evaluation rating when determining the compensation amount of the system administrator. For example, the compensation amount determination unit 170 may set a higher compensation payment rate for a system administrator with a higher evaluation rating. In addition, when the failure prediction information transmission unit 160, a description of which will follow, detects a system administrator who will transmit failure prediction information, the failure prediction information transmission unit may preferentially select a system administrator with a high evaluation rating in consideration of the evaluation rating.

The terminal interface unit (I/F) 130 provides a communication interface with an arbitrary terminal device (e.g., a cellular phone or a tablet computer) capable of accessing a communication network, and provides an interface with the system administrator terminal device 30 possessed by the system administrator or the operator terminal device 40 possessed by the system operator.

For example, under control of the control unit 140, the terminal interface unit (I/F) 130 transmits the failure prediction information of the actual photovoltaic power generation system 20 to at least one system administrator terminal device 30, the failure prediction information being transmitted to at least one system administrator terminal device 30 located within a predetermined distance from the actual photovoltaic power generation system 20 that is predicted to fail, and receives a failure recovery processing result from an administrator terminal device possessed by an arbitrary first system administrator who has responded first among the at least one system administrator terminal device 30.

Meanwhile, the control unit 140 stores the received information in the system administrator information management DB 120. At this time, the control unit 140 stores the response time of the first system administrator and the reception time of the failure recovery processing result in the administrator information management DB 120 in a state of being matched with the first system administrator. That is, the response time of the first system administrator and the reception time of the failure recovery processing result may be stored in a recovery processing history information field 125 of a record identified by a first system administrator ID.

In addition, the terminal interface unit (I/F) 130 may provide a communication interface with the system operator terminal device 40 accessed via the communication network, and may provide a three-dimensional image including virtual real-time photovoltaic power generation system operation information in response to a request from the system operator terminal device 40. To this end, the system operator terminal device 40 may transmit a real-time information request signal including identification information of an actual photovoltaic power generation system for which the real-time operation information is to be checked, and the terminal interface unit 130 may, upon receiving the real-time information request signal, receive real-time operation information of the simulated photovoltaic power generation system corresponding to the identification information included in the real-time information request signal from the simulated photovoltaic power generation system information management DB 112 and may transmit the same to the system operator terminal device 40. In this case, the real-time operation information of the simulated photovoltaic power generation system may be a three-dimensional image implemented using digital twin technology.

The control unit 140 controls the operation of the O&M management platform server 100 according to a preset control algorithm, and may control the operation of the failure diagnosis unit 150, the failure prediction information transmission unit 160, the compensation amount determination unit 170, the compensation payment unit 180, and the simulated photovoltaic power generation system generation unit 190 according to the control algorithm or information requested via the terminal interface unit 130.

The failure diagnosis unit 150 estimates the point-specific output data when the simulated photovoltaic power generation system is virtually operated under the same conditions as the operating conditions of the actual photovoltaic power generation system, and predicts whether the actual photovoltaic power generation system has failed based on the estimated data and the actual measurement data. An example of the configuration of the failure diagnosis unit 150 therefor is illustrated in FIG. 4. Referring to FIG. 4, the failure diagnosis unit 150 includes a weather information reception portion 151, a power generation estimation portion 152, an actual measurement data reception portion 153, a power generation calculation portion 154, and a failure analysis portion 155.

The weather information reception portion 151 receives weather information including real-time weather environment information (e.g., temperature, the amount of precipitation, wind direction, wind speed, humidity, sunlight, and fine dust concentration) and weather prediction information (e.g., weather environment information during a predetermined period of time in the future) of the area in which the actual photovoltaic power generation system 20 is installed from the meteorological agency server 10 connected via the communication network. At this time, the weather information reception portion 151 may receive the real-time weather environment information and the weather prediction information at every preset weather information reception cycle. For example, the weather information reception portion 151 may receive the real-time weather environment information in 15 minute units, and may receive the weather prediction information in 3 to 7 day units.

The power generation estimation portion 152 estimates the point-specific output data by reflecting the past power generation information stored in the actual photovoltaic power generation system information management DB 111 and the weather prediction information received through the weather information receiving portion 151 into the simulated photovoltaic power generation system for each actual photovoltaic power generation system. For example, the power generation estimation portion 152 may classify conditions that, are similar to the next day's weather environment and input conditions based on the operation information of the actual photovoltaic power generation system 20 that has been operated for 30 days and may input information predicted based on this value to estimate the point-specific output data, or may predict insolation when rain or snow is predicted in the area based on the weather information and may estimate point-specific output data according to the system specifications based on the predicted insolation.

The actual measurement data reception portion 153 receives at least one actual measurement datum from the actual photovoltaic power generation system. In this case, the actual measurement data is data output from each of the points (e.g., string input/output, junction box input/output terminals, and inverter input/output terminals) of the actual photovoltaic power generation system 20, and may include output current/output voltage/output power/temperature/humidity of each thereof. For example, the actual measurement data reception portion 153 may receive output current/output voltage/output power/temperature/humidity measurement values for each string constituting the actual photovoltaic power generation system 20.

The failure analysis portion 155 compares the estimated data estimated by the power generation estimation portion 152 for each actual photovoltaic power generation system with the actual measurement data received by the actual measurement data reception portion 153, and when the difference exceeds a predetermined error range, predicts failure of the actual photovoltaic power generation system, and analyzes the cause thereof. At this time, the failure analysis portion 155 may utilize multi-level information for comparison of the power generation. For example, the failure analysis portion 155 may predict whether an arbitrary first actual photovoltaic power generation system has failed by comparing the estimated data estimated in stages at points, such as strings, junction boxes, and inverters, constituting the first actual photovoltaic power generation system with the actual measurement data received at each point. At this time, the failure analysis portion 155 may predict not only the failure of the entirety of the system but also the location of the failure by comparing the estimated data and the actual measurement data with each other step by step as described above. For example, when the difference between the output voltage measured at a first string of a first junction box of the actual photovoltaic power generation system and the voltage estimated to be output at a first string of a first junction box of the simulated photovoltaic power generation system exceeds the error range, it may be determined that failure or an error has occurred at the first string of the first junction box.

Meanwhile, when the failure is predicted as described above, the failure analysis portion 155 may analyze the cause of the failure based on weather information of the area where the first actual photovoltaic power generation system is installed, geographical information of the area, and ambient environmental information at the current time when the failure is predicted (e.g., current humidity and fine dust concentration). For example, when the output voltage of a specific string is significantly lower than the output voltage of the surrounding strings, i.e., lower to the extent that exceeds the error range, the failure analysis portion 155 may analyze the cause of the failure by determining whether there is a factor that hinders insolation of the string, whether there is leakage current in an output line of the string, or whether the degree of pollution caused by fine dust affects lowering of the output voltage.

In addition, when failure is predicted, the failure analysis portion 155 outputs the failure prediction information to the failure prediction information transmission unit 160. At this time, the failure analysis portion 155 may directly transmit the failure prediction information to the failure prediction information transmission unit 160, or may transmit the failure prediction information to the failure prediction information transmission portion via the control unit 140. In this case, the failure prediction information may include identification information of the first actual photovoltaic power generation system that is predicted to fail, information (e.g., the first string of the first junction box) of the location in the first actual photovoltaic power generation system that is predicted to fail, time information of the future at which a failure is predicted, information of the current time at which the failure is predicted, and the analysis result of the cause of the failure, as in the example.

The failure prediction information transmission unit 160 transmits the failure prediction information to at least one system administrator. At this time, the failure prediction information transmission unit 160 may transmit the failure prediction information to at least one system administrator located within a predetermined distance from the failure prediction point where the failure is predicted. To this end, the failure prediction information transmission unit 160 may determine the failure prediction point by detecting the geographic information of the first actual photovoltaic power generation system from the actual photovoltaic power generation system information management DB 111, may detect a system administrator whose real-time location is within a predetermined distance from the failure prediction point in the system administrator information management DB 120, and may transmit the failure prediction information to the detected system administrator.

Meanwhile, the failure prediction information transmission unit 160 may approximately calculate the time required for the system administrator to arrive at the failure prediction point based on the failure prediction point and the real-time location information of the system administrator, and may select the at least one system administrator in order of being able to quickly arrive at the failure prediction point based on the time required. In addition, the failure prediction information transmission unit 160 may classify the system administrators into predetermined groups based on the time required, may sequentially select system administrators belonging to the group with a shorter time required from system administrators belonging to the group with a longer time required, until a response message for failure recovery is received, and may transmit the failure prediction information thereto.

The compensation amount determination unit 170 determines the compensation amount to be paid to the system administrator who participated in the recovery operation based on the duration from the prediction of the failure of the first actual photovoltaic power generation system to the recovery from the failure. For example, the compensation amount determination unit 170 may determine the compensation amount in inverse proportion to the time required to recover from the failure. This has the effect of encouraging the system administrators to quickly participate in failure recovery by increasing compensation for fast recovery, since the longer the time from the occurrence of the failure to the recovery from the failure, the greater the power consumption and the greater the inconvenience to electricity users.

The compensation payment unit 180 pays a predetermined compensation amount to the system administrator who participated in the recovery work, and pays the compensation amount determined by the compensation amount determination unit 170 to the first system administrator. At this time, a compensation payment method may be implemented by referring to a known online payment method or the like.

The simulated photovoltaic power generation system generation unit 190 generates a simulated photovoltaic power generation system having the same system specifications and installation information as each actual photovoltaic power generation system for each of at least one actual photovoltaic power generation system. At this time, the simulated photovoltaic power generation system generation unit 190 may implement the simulated photovoltaic power generation system as a three-dimensional image using a digital twin method, and may generate the simulated photovoltaic power generation system by reflecting the real-time system specification information and point-specific actual measurement data of the actual photovoltaic power generation system into the three-dimensional image.

In addition, the simulated photovoltaic power generation system generation unit 190 may generate a three-dimensional image including a plurality of actual measurement data received from the actual photovoltaic power generation system, real-time weather environment information collected from the meteorological agency server, and virtual real-time photovoltaic power generation system operation information having the installation location information of the actual photovoltaic power generation system reflected thereinto. At this time, the three-dimensional image may be generated using any of various known methods (e.g., a digital twin method).

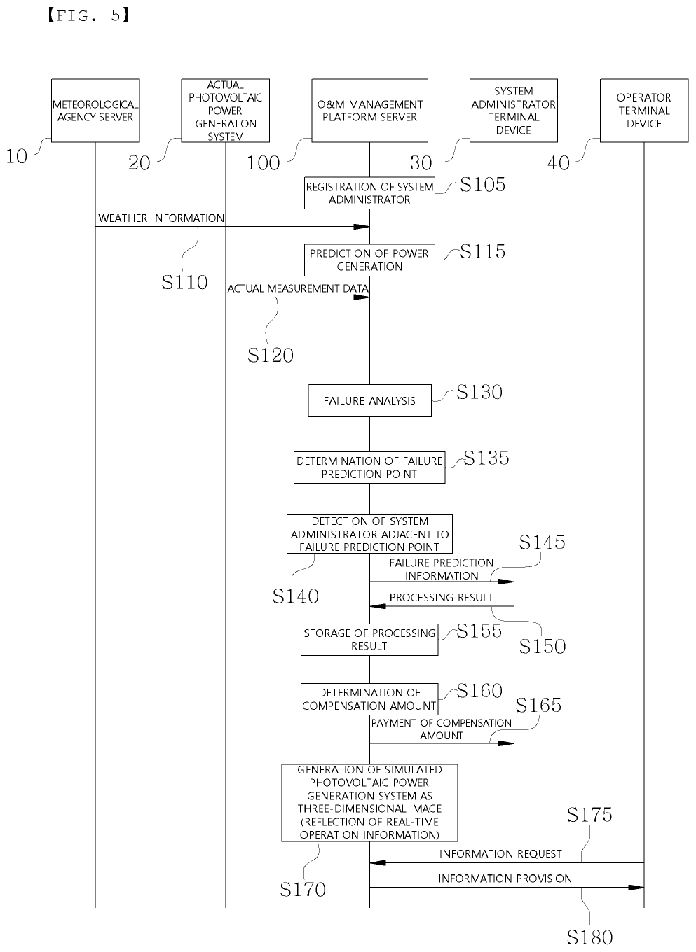

FIG. 5 is a schematic flowchart showing a method of performing operation and maintenance of a photovoltaic power generation system using an O&M management platform server of a photovoltaic power generation system according to one embodiment of the present invention, wherein a method of the O&M management platform server 100 according to the present invention, which stores arbitrary photovoltaic power generation system information and information of a virtual simulated photovoltaic power generation system that is implemented so as to have the same operating conditions as each actual photovoltaic power generation system, performing O&M of a photovoltaic power generation system in cooperation with the meteorological agency server 10, the actual photovoltaic power generation system 20, the system administrator terminal device 30, and the system operator terminal device 40 is illustrated.

To this end, the O&M management platform server 100 may first perform an actual system information storage step (not shown) of, for each of actual photovoltaic power generation systems, storing actual photovoltaic power generation system information including initial system specification information of each of the actual photovoltaic power generation systems, periodically updated real-time system specification information, geographical information of the area in which the actual photovoltaic power generation system is installed, a power generation estimation value set at the time of design, past power generation information based on past environmental data during a preset predetermined period of time, and point-specific actual measurement data collected in real time and a simulated system information storage step (not shown) of storing virtual simulated photovoltaic power generation system information corresponding to each of the actual photovoltaic power generation systems and storing system specification information reflecting real-time system specifications of the actual photovoltaic power generation system and the estimated data.

In step S105, the O&M management platform server 100 registers a system administrator. That is, in step S105, the O&M management platform server 100 registers a system administrator (or an expert) capable of performing recovery operations in the event of failure of the photovoltaic power generation system. To this end, the O&M management platform server 100 may collect the system administrator information on-line and off-line, and may collect information from a specific organization that manages a plurality of pieces of system administrator information, or may collect and register necessary information in response to a request of each of the system administrators. In addition, the O&M management platform server 100 may store system administrator information including identification information, terminal device information, and real-time location of the system administrator. In this case, an example of a field configuration of the system administrator information management DB 120 configured to store the system administrator information is illustrated in FIG. 3. A detailed description of the database configured to store/manage the system administrator information has already been given with reference to FIG. 3.

In steps S110 to S130, the O&M management platform server 100 estimates the point-specific output data of the actual photovoltaic power generation system 20 when the simulated photovoltaic power generation system is virtually operated under the same conditions as the operating conditions of the actual photovoltaic power generation system 20, and predicts whether the actual photovoltaic power generation system 20 has failed based on the actual measured data collected for each point during operation of the actual photovoltaic power generation system 20 and the estimated data.

To this end, in step S110, the O&M management platform server 100 receives weather information including real-time weather environment information (e.g., temperature, the amount of precipitation, wind direction, wind speed, humidity, sunlight, and fine dust concentration) and weather prediction information (e.g., weather environment information during a predetermined period of time in the future) of the area in which the actual photovoltaic power generation system 20 is installed from the meteorological agency server 10 connected via the communication network. In step S115, the O&M management platform server 100 estimates the point-specific output data by reflecting the stored past power generation information and the weather prediction information received in step S110 in the simulated photovoltaic r generation system for each actual photovoltaic power generation system.

For example, the O&M management platform server 100 may classify conditions that are similar to the next day's weather environment and input conditions based on the operation information of the actual photovoltaic power generation system 20 that has been operated for 30 days and may input information predicted based on this value to estimate the point-specific output data, or may predict insolation when rain or snow is predicted in the area based on the weather information and may estimate daily power generation according to the system specifications based on the predicted insolation.

Meanwhile, in step S120, the O&M management platform server 100 receives at least one actual measurement datum from the actual photovoltaic power generation system. In this case, the actual measurement data is data output from each of the points (e.g., string input/output, junction box input/output terminals, and inverter input/output terminals) of the actual photovoltaic power generation system 20, and may include output current/output voltage/output power/temperature/humidity of each thereof. For example, in step S120, the O&M management platform server 100 may receive output current/output voltage/output power/temperature/humidity measurement values for each string constituting the actual photovoltaic power generation system 20.

In step S130, the O&M management platform server 100 analyzes failure. The O&M management platform server compares the estimated data estimated in step S115 with the actual measurement data received in step S120, and when the difference exceeds a predetermined error range, predicts failure of the actual photovoltaic power generation system, and analyzes the cause thereof. A detailed method of predicting the failure and analyzing the cause thereof has already mentioned in the description of the failure analysis portion 155 made with reference to FIG. 4.

Meanwhile, when failure of a first actual photovoltaic power generation system is predicted in steps S110 to S130, in steps S135 and S140, the O&M management platform server 100 detects at least one of the system administrators registered in step S105.

To this end, in step S135, the O&M management platform server 100 determines a failure prediction point, and in step S140, the O&M management platform server detects a system administrator adjacent to the failure prediction point. A detailed method of determining the failure prediction point and detecting the system administrator adjacent to the failure prediction point has already been mentioned in the description of the failure prediction information transmission portion 160 given with reference to FIG. 2.

In step S145, the O&M management platform server 100 transmits the failure prediction information of the first actual photovoltaic power generation system to the detected system administrator. That is, in step S145, the O&M management platform server 100 transmits the failure prediction information to the terminal device (i.e., the system administrator terminal device) 30 possessed by the detected system administrator. In this case, the failure prediction information may include identification information of the first actual photovoltaic power generation system that is predicted to fail, information (e.g., a first string of a first junction box) of the location in the first actual photovoltaic power generation system that is predicted to fail, time information of the future at which a failure is predicted, information of the current time at which the failure is predicted, and the analysis result of the cause of the failure.

In step S150, upon receiving the failure prediction information, the system administrator terminal device 30 may process the failure recovery, and may transmit the processing result to the O&M management platform server 100.

At this time, the system administrator terminal device 30 first transmits a response message to inform the O&M management platform server 100 that the system administrator terminal device has received the failure prediction information, and the system administrator visits the actual photovoltaic power generation system 20 for which the failure is predicted to process the failure recovery, wherein the system administrator visits the failure location included in the failure prediction information to check whether there is a failure and performs a recovery operation in case of a failure. To this end, first, the system administrator may read a QR code attached to each device constituting the actual photovoltaic power generation system 20 using the terminal device 30, and may transmit the information to the O&M management platform server 100. This is to confirm whether the system administrator has normally visited the failure location included in the failure prediction information.

Meanwhile, when recovery from the failure is completed, the system administrator accesses the O&M management platform server 100 using the system administrator terminal device 30 and transmits the processing result thereto.

Upon receiving the processing result from the system administrator terminal device 30, the O&M management platform server 100 stores the processing result in step S155. That is, in step S155, the O&M management platform server 100 stores the processing result and also stores the response time at which the system administrator transmitted the response message, and the time at which the failure recovery processing result was received. In particular, the O&M management platform server 100 stores the information in a separate storage space to configured store system administrator information (e.g., the system administrator information management DB) in the state in which the system administrator is matched with the processing result. This is to provide compensation to each system administrator who participated in failure recovery based on the time spent on failure recovery.

In step S160, the O&M management platform server 100 determines a compensation amount for the system administrators who participated in the failure recovery. To this end, the O&M management platform server 100 calculates the duration from predicting the failure of the first actual photovoltaic power generation system to recovering from the failure, and determines a compensation amount to be paid to the system administrator who participated in the failure recovery based on the duration. In particular, the O&M management platform server 100 may determine the compensation amount in inverse proportion to the time required to recover from the failure. This is to encourage the system administrators to quickly participate in the failure recovery by increasing compensation for fast recovery, since the longer the time from the occurrence of the failure to the recovery from the failure, the greater the power consumption and the greater the inconvenience to electricity users.

In step S165, the O&M management platform server 100 pays the compensation amount determined in step S160 to the system administrator. At this time, a compensation payment method may be implemented by referring to a known online payment method or the like. For example, points may be paid to the system administrator terminal device 30, or the compensation amount may be paid using deposit information stored at the time of system administrator registration.

In step S170, the O&M management platform server 100 implements the simulated photovoltaic power generation system as a three-dimensional image using a digital twin method. In particular, in step S170, the O&M management platform server 100 may generate a three-dimensional image including a plurality of actual measurement data received from the actual photovoltaic power generation system, real-time weather environment information collected from the meteorological agency server, and virtual real-time photovoltaic power generation system operation information having the installation location information of the actual photovoltaic power generation system reflected therein. At this time, the simulated photovoltaic power generation system may be implemented by the O&M management platform server 100, or may be implemented using a separate apparatus for generating a three-dimensional image using digital twin technology and may be loaded into the O&M management platform server 100.

In steps S175 and S180, the O&M management platform server 100 provides the three-dimensional image including the virtual real-time photovoltaic power generation system operation information in response to a request from the system operator terminal device 40 connected to the O&M management platform server 100 via the communication network. At this time, the O&M management platform server 100 may provide the real-time operation information by overwriting the actual measurement data or the estimated data on the simulated photovoltaic power generation system information in the form of a registered three-dimensional image (i.e., a virtual three-dimensional image of the actual photovoltaic power generation system).

Meanwhile, the system operator is a user authorized to access the operation information of the photovoltaic power generation system.

As described above, the present invention is characterized in that, after implementing a virtual simulated photovoltaic power generation system for each of at least one actual photovoltaic power generation system, it is possible to predict a failure of an arbitrary actual photovoltaic power generation system based on the difference between actual measurement data of the actual photovoltaic power generation system and estimated data of the simulated photovoltaic power generation system and to notify a system operator adjacent to the actual photovoltaic power generation system that is predicted to fail among pre-registered system operators of the same such that the system operator can quickly respond to the failure.

In addition, the present invention is characterized in that it is possible to provide differentiated compensation amount to a system administrator who has participated in the recovery from the failure of the photovoltaic power generation system according to the speed of response, whereby it is possible to more actively respond to the failure of the photovoltaic power generation system.

Furthermore, the present invention is characterized in that it is possible to provide real-time operation information of the virtual simulated photovoltaic power generation system as a three-dimensional image using digital twin technology such that a user having no specialized knowledge of the system can intuitively quickly recognize the operating state of the photovoltaic power generation system.

Although the embodiment of the present invention has been described above, the scope of right of the present invention is not limited thereto and includes all alterations and modifications within a range easily changed and recognized as being equivalent by a person having ordinary skill in the art to which the present invention pertains from the embodiment of the present invention.

### DESCRIPTION OF REFERENCE NUMERALS

100: O&M management platform server 110: System information management DB
120: System administrator information management DB 130: Terminal interface unit
140: Control unit 150: Failure diagnosis unit
160: Failure prediction information transmission unit 170: Compensation amount determination unit
180: Compensation payment unit
190: Simulated photovoltaic power generation system generation unit

1. An apparatus for providing an operation and maintenance management platform service of a photovoltaic power generation system, the apparatus comprising:
a simulated photovoltaic power generation system generation unit configured to generate a simulated photovoltaic power generation system having the same system specifications and installation information as each actual photovoltaic power generation system for each of at least one actual photovoltaic power generation system;
a system information storage unit configured to store system specifications and installation information of each of the actual photovoltaic power generation systems, point-specific actual measurement data collected in real time during operation, and simulated photovoltaic power generation system information corresponding thereto;
a failure diagnosis unit configured to estimate point-specific output data when the simulated photovoltaic power generation system is virtually operated under the same conditions as operating conditions of the actual photovoltaic power generation system corresponding thereto and to compare the estimated data with the actual measurement data to predict whether the actual photovoltaic power generation system has failed;
an administrator information storage unit configured to store system administrator information registered as system administrators capable of performing a recovery operation in the event of a failure of the actual photovoltaic power generation system; and
a failure prediction information transmission unit configured to transmit failure prediction information to at least one of the system administrators registered in the administrator information storage unit when a failure of an arbitrary first actual photovoltaic power generation system is predicted by the failure diagnosis unit.

2. The apparatus according to claim 1, wherein the system information storage unit comprises:
an actual system information storage portion configured to store actual photovoltaic power generation system information comprising initial system specification information of each of the actual photovoltaic power generation systems, periodically updated real-time system specification information, geographic information of an area in which the actual photovoltaic power generation system is installed, a power generation estimate value established at the time of design, past power generation information based on past environmental data during a predetermined period of time, and point-specific actual measurement data collected in real time; and
a simulated system information storage portion configured to store virtual simulated photovoltaic power generation system information corresponding to each of the actual photovoltaic power generation systems and to store simulated system specification information reflecting real-time system specifications of the actual photovoltaic power generation system corresponding thereto and the estimated data.

3. The apparatus according to claim 2, wherein the failure diagnosis unit comprises:
a weather information reception portion configured to receive weather information comprising real-time weather environment information and weather prediction information from a meteorological agency server connected d via a communication network;
a power generation estimation portion configured to estimate the point-specific output data by reflecting the past power generation information stored in the actual system information storage portion and the weather prediction information received through the weather information reception portion into the simulated photovoltaic power generation system corresponding thereto for each actual photovoltaic power generation system;
an actual measurement data reception portion configured to receive point-specific actual measurement data from the actual photovoltaic power generation system; and
a failure analysis portion configured to compare the estimated data with the actual measurement data for each point of the actual photovoltaic power generation system and when a difference exceeds a predetermined error range, to predict a failure of the actual photovoltaic power generation system corresponding thereto and to analyze a cause thereof.

4. The apparatus according to claim 2, wherein the administrator information storage unit stores system administrator information comprising identification information, terminal device information, and real-time location information of the system administrator.

5. The apparatus according to claim 4, further comprising:
a terminal interface unit configured to provide a communication interface with an arbitrary terminal device capable of accessing a communication network, wherein
the failure prediction information transmission unit transmits the prediction failure information to an administrator terminal device possessed by the system administrator through the terminal interface unit, and
the failure prediction information transmission unit determines a failure prediction point by detecting the geographic information of the first actual photovoltaic power generation system from the actual system information storage portion, detects at least one system administrator whose real-time location is within a predetermined distance from the failure prediction point in the administrator information storage unit, and transmits the failure prediction information to an administrator terminal device possessed by the detected system administrator.

6. The apparatus according to claim 5, wherein
the terminal interface unit receives a failure recovery processing result of the first actual photovoltaic power generation system from an administrator terminal device possessed by an arbitrary first system administrator who has responded first among at least one system administrator who has received the failure prediction information, and
the administrator information storage unit stores a response time of the first system administrator and a reception time of the failure recovery processing result.

7. The apparatus according to claim 6, further comprising:
a compensation amount determination unit configured to determine a compensation amount to be paid to the first system administrator based on a duration from prediction of a failure of the first actual photovoltaic power generation system to recovery from the failure; and
a compensation payment unit configured to pay the compensation amount determined by the compensation amount determination unit to the first system administrator.

8. The apparatus according to claim 5, wherein the simulated photovoltaic power generation system generation unit implements the simulated photovoltaic power generation system as a three-dimensional image using a digital twin method, and generates the simulated photovoltaic power generation system by reflecting the real-time system specification information and point-specific actual measurement data of the actual photovoltaic power generation system corresponding thereto in the three-dimensional image.

9. The apparatus according to claim 8, wherein
the terminal interface unit provides a communication interface with a system operator terminal device connected via the communication network, and
the apparatus provides real-time operation information of the actual photovoltaic power generation system corresponding thereto in response to a request of the system operator terminal device and displays the real-time operation information on the simulated photovoltaic power generation system implemented as the three-dimensional image.

10. A method of performing operation and maintenance of a photovoltaic power generation system using an apparatus for providing an operation and maintenance management platform service of a photovoltaic power generation system, the apparatus configured to store arbitrary actual photovoltaic power generation system information and virtual simulated photovoltaic power generation system information implemented so as to have the same system specifications and installation information as each actual photovoltaic power generation system, the method comprising:
an administrator information storage step of, by the apparatus for providing the operation and maintenance management platform service, storing system administrator information registered as system administrators capable of performing a recovery operation in the event of a failure of the photovoltaic power generation system;
failure diagnosis step of, by the apparatus for providing the operation and maintenance management platform service, estimating point-specific output data when the simulated photovoltaic power generation system is virtually operated under the same conditions as operating conditions of the actual photovoltaic power generation system corresponding thereto and predicting whether the actual photovoltaic power generation system has failed based on actual measured data collected for each point during operation of the actual photovoltaic power generation system and the estimated data;
an administrator detection step of, by the apparatus for providing the operation and maintenance management platform service, detecting at least one of the system administrators registered in the administrator information storage step when a failure of an arbitrary first actual photovoltaic power generation system is predicted in the failure diagnosis step; and
a failure prediction information transmission step of, by the apparatus for providing the operation and maintenance management platform service, transmitting failure prediction information of the first actual photovoltaic power generation system to the detected system administrator.

11. The method according to claim 10, wherein the method further comprises:
an actual system information storage step of storing actual photovoltaic power generation system information comprising initial system specification information of each of the actual photovoltaic power generation systems, periodically updated real-time system specification information, geographic information of an area in which the actual photovoltaic power generation system is installed, a power generation estimate value established at the time of design, past power generation information based on past environmental data during a predetermined period of time, and point-specific actual measurement data collected in real time; and
a simulated system information storage step of storing virtual simulated photovoltaic power generation system information corresponding to each of the actual photovoltaic power generation systems and storing system specification information reflecting real-time system specifications of the actual photovoltaic power generation system corresponding thereto and the estimated data.

12. The method according to claim 11, wherein the failure diagnosis step comprises:
a weather information reception step of receiving weather information comprising real-time weather environment information and weather prediction information from a meteorological agency server connected via a communication network;
a power generation estimation step of estimating the point-specific output data by reflecting the past power generation information stored actual system in the information storage step and the weather prediction information received in the weather information reception step into the simulated photovoltaic power generation system corresponding thereto for each actual photovoltaic power generation system;
an actual measurement data reception step of receiving point-specific actual measurement data from the actual photovoltaic power generation system; and
a failure analysis step of comparing the estimated data with the actual measurement data for each point of the actual photovoltaic power generation system and, when a difference exceeds a predetermined error range, predicting a failure of the actual photovoltaic power generation system corresponding thereto and analyzing a cause thereof.

13. The method according to claim 11, wherein the administrator information storage step stores system administrator information comprising identification information, terminal device information, and real-time location information of the system administrator.

14. The method according to claim 13, wherein the administrator detection step comprises:
a first step of determining a failure prediction point from the geographic information of the first actual photovoltaic power generation system stored in the actual system information storage step; and
a second step of detecting at least one system administrator whose real-time a location is within predetermined distance from the failure prediction point.

15. The method according to claim 14, further comprising:
a processing result reception step of receiving a failure recovery processing result of the first actual photovoltaic power generation system from an administrator terminal device possessed by an arbitrary first system administrator who has responded first among at least one system administrator who has received the failure prediction information; and
a processing result storage step of storing a response time and a reception time of the failure recovery processing result in a state of being matched with the first system administrator.

16. The method according to claim 15, further comprising:
a duration calculation step of calculating a duration from prediction of a failure of the first actual photovoltaic power generation system to recovery from the failure;
a compensation amount determination step of determining a compensation amount to be paid to the first system administrator based on the duration; and
a compensation payment step of paying the compensation amount determined in the compensation amount determination step to the first system administrator.

17. The method according to claim 16, further comprising:
a simulated photovoltaic power generation system generation step of implementing the simulated photovoltaic power generation system as a three-dimensional image using a digital twin method and generating the simulated photovoltaic power generation system by reflecting the real-time system specification information and point-specific actual measurement data of the actual photovoltaic power generation system corresponding thereto in the three-dimensional image, wherein
the simulated system information storage step stores simulated photovoltaic power generation system information implemented as the three-dimensional image.

18. The method according to claim 17, further comprising a three-dimensional image provision step of providing real-time operation information of the actual photovoltaic power generation system corresponding thereto in response to a request of a system operator terminal device connected via the communication network and displaying the real-time operation information on the simulated photovoltaic power generation system implemented as the three-dimensional image.
